(19) United States
(12) Patent Application Publication
(10) Pub. No.: US 2024/0230716 A1
(43) Pub. Date: Jul. 11, 2024

(54) SOCKET DEVICE FOR TESTING ICs

(71) Applicants: Dong Weon HWANG, Seongnam-si (KR); Jae Baek HWANG, Seongnam-si (KR); HICON CO., LTD., Seongnam-si (KR)

(72) Inventors: Dong Weon HWANG, Seongnam-si (KR); Jae Baek HWANG, Seongnam-si (KR); Jae Woo PARK, Yongin-si (KR); Hyung Suk PARK, Cheonan-si (KR); Seung Woo Rhee, Seongnam-si (KR)

(73) Assignees: Dong Weon HWANG, Seongnam-si (KR); Jae Baek HWANG, Seongnam-si (KR); HICON CO., LTD., Seongnam-si (KR)

(21) Appl. No.: 18/402,668

(22) Filed: Jan. 2, 2024

(30) Foreign Application Priority Data
Jan. 10, 2023 (KR) 10-2023-0003636

(51) Int. Cl. G01R 1/04

(52) U.S. Cl. CPC G01R 1/0466

(57) ABSTRACT

Proposed is a socket device for testing integrated circuits (ICs). The socket device has an excellent noise shielding effect between signal probes and is easy to manufacture. The socket device with ground probes (10) and signal probes (20) includes an insulating socket body (110) having ground holes (110a) to accommodate the ground probes (10) and signal holes (110b) to accommodate the signal probes (20), a conductive ground plating layer (121) formed on the surface of each of the ground holes (110a), and a conductive shielding element (130) provided to penetrate the upper and lower surfaces of the socket body (110) to shield noise between adjacent signal probes (20).

### CROSS REFERENCE TO RELATED APPLICATION

The present application claims priority to Korean Patent Application No. 10-2023-0003636, filed Jan. 10, 2023, the entire contents of which is incorporated herein for all purposes by this reference.

### BACKGROUND OF THE INVENTION

### Field of the Invention

The present disclosure relates to a socket device used for testing integrated circuits (ICs).

### Description of the Related Art

An integrated circuit (IC) is a high-density integration of electronic circuits, and during the manufacturing process, each electronic circuit undergoes a testing process to determine whether or not the electronic circuit is functional. The test process uses an inspection device that applies a test signal to leads of an IC being inspected, and the inspection device is not directly connected to the leads of the IC under test, but is connected through a test socket. The test socket consists of a probe that connects each lead of the IC to a terminal of a test printed circuit board (PCB) of the inspection device, and a socket that supports the probe. Probes and sockets that make up a test socket come in various forms, taking into account the operating frequency of an IC, type of lead (BGA, LGA, etc.), and pitch between leads.

FIG. 1 is a cross-sectional view of a conventional socket device used for testing integrated circuits (ICs). The socket device includes a plurality of probes 1 and socket bodies 2 and 3 supporting the plurality of probes 1. The socket bodies 2 and 3 are for electrically insulating the plurality of probes 1, and are composed of an upper body 2 that supports the upper ends of the probes 1 and a lower body 3 that supports the lower ends of the probes 1. The probes 1 are supported on the top and bottom of the socket bodies 2 and 3, have own elasticity thereof in the longitudinal direction (vertical direction), and electrically connect leads of an IC mounted on the top of the socket device and terminals (pads) of a test PCB at the bottom of the socket device.

Meanwhile, advances in ICs have led to increased speeds and decreased lead pitch, which makes crosstalk between probes an issue, and thus noise shielding between probes is becoming a very important factor.

In order to solve this problem, various test socket device technologies are being developed. For example, a coaxial-type probe is adopted by plating the inner surface of a hole where the probe is accommodated in an insulator socket body, or a socket body is made of metal to shield noise between probes. However, in the case of conventional socket devices, due to IC miniaturization, higher speed, rapid increase in the number of leads, and narrower lead pitch, there are many difficulties in shielding noise between probes, and the manufacturing process is becoming complex and difficult.

### Documents of Related Art

(Patent Document 0001) Korean Patent No. 10-1534778 (published Jul. 9, 2015)

### SUMMARY OF THE INVENTION

Accordingly, the present disclosure has been made keeping in mind the above problems occurring in the related art, and the present disclosure is intended to provide a socket device for testing integrated circuits (ICs) that has an excellent noise shielding effect between probes and is easy to manufacture (hereinafter abbreviated as “socket device”).

In order to achieve the above objective, according to an embodiment of the present disclosure, there is provided a socket device for testing integrated circuits (ICs). The socket device with ground probes and signal probes, includes: an insulating socket body having ground holes to accommodate the ground probes and signal holes to accommodate the signal probes; a conductive ground plating layer formed on a surface of each of the ground holes; and a conductive shielding element provided to penetrate upper and lower surfaces of the socket body to shield noise between adjacent signal probes.

Preferably, the shielding element may be placed between signal holes that are the nearest neighbors to each other. More preferably, the shielding element may include: a via hole formed through the upper and lower surfaces of the socket body; and a conductive shield plating layer formed on a surface of the via hole. More preferably, the shield plating layer may be electrically connected to the ground plating layer.

Preferably, the socket body may include: an upper body portion provided with a first support portion supporting a top of each of the probes; and a lower body portion provided with a second support portion supporting a bottom of each of the probes and assembled with the upper body portion.

More preferably, upper body portion may include: a first upper body portion through which a first guide hole is formed where an upper tip of each of the probes protrudes; and a second upper body portion through which a first receiving hole having a larger inner diameter than the first guide hole and communicating with the first guide hole is formed, and assembled with the first upper body portion, and the lower body portion may include: a first lower body portion through which a second guide hole is formed where a lower tip of each of the probes protrudes; and a second lower body portion through which a second receiving hole having a larger inner diameter than the second guide hole and communicating with the second guide hole and the first receiving hole is formed, and assembled with the second upper body portion and the first lower body portion.

Preferably, the socket device may further include: a conductive signal plating layer formed on a surface of each of the signal holes;

and an insulating layer formed on a surface of the signal plating layer to electrically insulate each of the signal probes and the signal plating layer.

A socket device for testing integrated circuits (ICs) according to the present disclosure has an excellent noise shielding effect between signal probes and is easy to manufacture. The socket device having a plurality of ground probes and a plurality of signal probes includes: an insulating socket body with a ground hole and a signal hole; a conductive ground plating layer formed on the surface of the ground hole; and a conductive shielding element provided to penetrate the upper and lower surfaces of the socket body to shield noise between adjacent signal probes.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view of a conventional socket device;

FIG. 2 is a plan view of a socket device according to a preferred embodiment of present disclosure;

FIG. 3 is a cross-sectional view taken along line A-A of FIG. 2;

FIG. 4 is a cross-sectional view taken along line B-B of FIG. 2;

FIGS. 5A to 5D show a probe used in the socket device of the present disclosure, and exploded views of the probe;

FIG. 6 is a plan view of a socket device according to another embodiment of present disclosure;

FIG. 7 is a cross-sectional view taken along line C-C of FIG. 6;

FIG. 8 is an exploded view of FIG. 7;

FIG. 9 is a plan view of a socket device according to still another embodiment of present disclosure;

FIG. 10 is a cross-sectional view of a socket device according to still another embodiment of present disclosure; and

FIG. 11 is a plan view of a socket device according to still another embodiment of present disclosure.

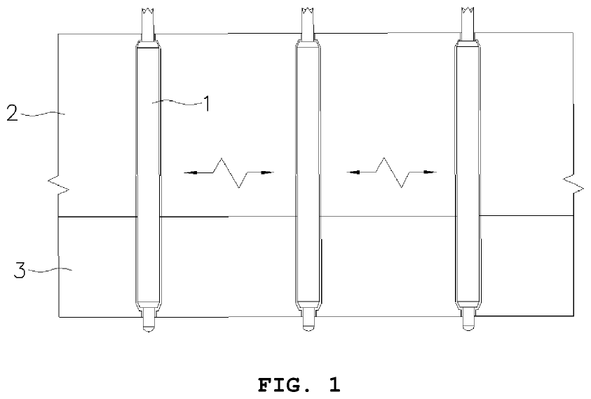

### DETAILED DESCRIPTION OF THE INVENTION

Terms and words used in this specification and claims should not be construed as limited to their ordinary or dictionary meanings, and should be interpreted as meaning and concept consistent with the technical idea of the present disclosure on the basis of the principle that an inventor can appropriately define terminological concepts to best describe his or her invention.

Accordingly, an embodiment described in this specification and the configuration shown in the drawings are only one of the most preferred embodiments of the present disclosure, and do not represent the entire technical idea of the present disclosure. Therefore, it should be understood that at the time of filing this application, there may be various equivalents and modifications that can replace the embodiment and the configuration.

Hereinafter, preferred embodiments of the present disclosure will be described in detail with the accompanying drawings. Meanwhile, in the drawings below, the size of certain components may be relatively exaggerated to aid understanding of the invention, and parts assigned the same reference numerals indicate the same components.

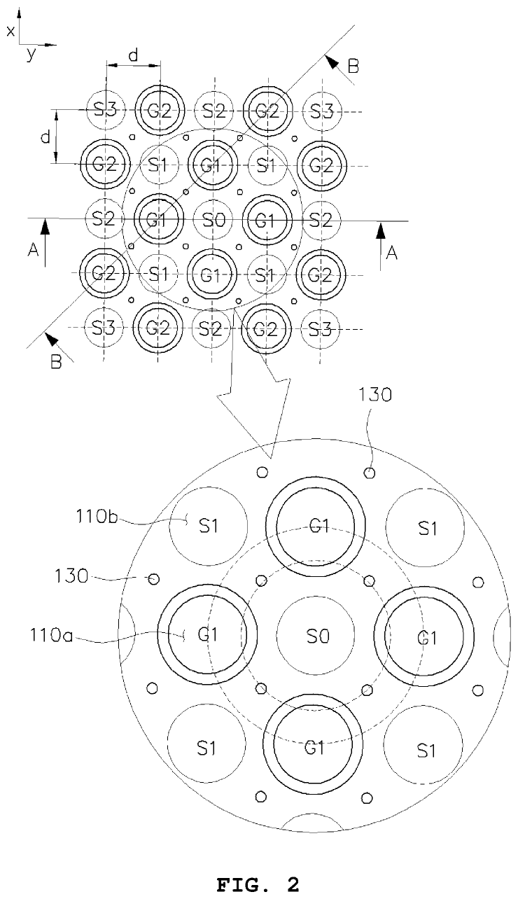

In a socket device, a probe is used to connect each lead of an integrated circuit (IC) and a pad of a test printed circuit board (PCB), and the placement of the probe is determined in correspondence with the lead location (pattern) of an IC to be inspected. Generally, in a socket device, a probe may be composed of a signal probe for transmitting signals, a ground probe for grounding, and a power probe for supplying power for circuit operation. The following description focuses on signal probes and ground probes, which occupy the majority of socket devices. FIG. 2 is a plan view showing the arrangement of ground holes and signal holes into which ground probes and signal probes are inserted. In general, the lead arrangement of an IC has a standardized pattern, usually square or diagonal. In this embodiment, a square pattern with a pitch between leads of d is illustrated, but it should be clearly understood that the present disclosure is not limited to a specific lead arrangement pattern. In the following description, the holes where the ground probe and signal probe are located are denoted by G and S, respectively, an arbitrary signal hole located in the center of the drawing is denoted as S0, and the ground hole and the signal hole arranged sequentially adjacent to the reference signal hole S0 are called a first signal hole S1 and a first ground hole G1.

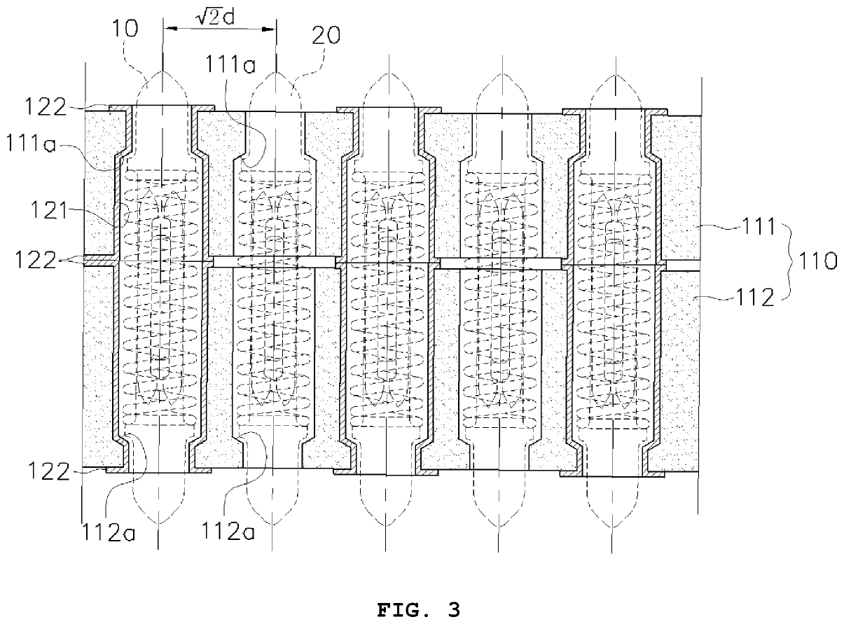

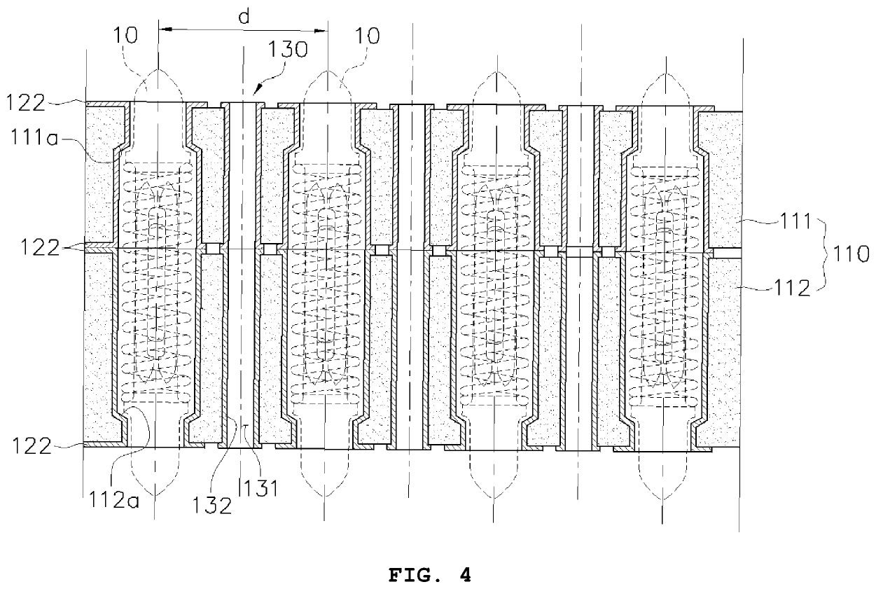

FIG. 3 is a cross-sectional view taken along line A-A of FIG. 2, and FIG. 4 is a cross-sectional view taken along line B-B of FIG. 2. Referring to FIGS. 2 to 4, a socket device according to the present embodiment includes: a socket body 110 made of an insulating material with a plurality of holes 110a and 110b formed to accommodate each of a plurality of probes 10 and 20; a conductive ground plating layer 121 formed on the surface of each of the ground holes 110a that accommodates each of the ground probes 10 among the holes 110a and 110b; and a conductive shielding element 130 provided to penetrate the upper and lower surfaces of the socket body 110.

In the present embodiment, the probes 10 and 20 maybe composed of the ground probe 10 and the signal probe 20 inserted into the ground hole 110a and the signal hole 110b, respectively. The ground probe 10 connects a ground lead of an IC and a ground terminal of a test PCB, and the signal probe 20 connects a signal lead of the IC and a signal terminal (pad) of the test PCB. The ground probe 10 and the signal probe 20 make elastic contact with the leads of the IC and the terminals (pads) of the test PCB, and may be provided by probes of the same structure.

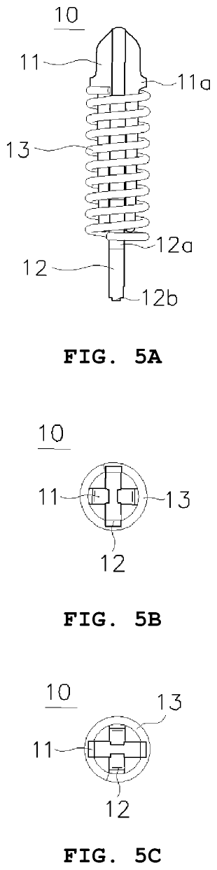

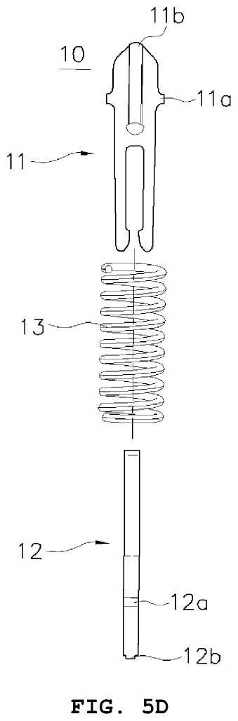

FIGS. 5A to 5D show a probe used in the socket device of the present disclosure, and exploded views of the probe. FIG. 5A is the front view, FIGS. 5B and 5C are the top view and the bottom view, respectively, and the FIG. 5D is the exploded view.

Referring to FIGS. 5A to 5D, the ground probe 10 includes: an upper contact pin 11; a lower contact pin 12 assembled by crossing the upper contact pin 11 in the longitudinal direction; and a spring 30 inserted between the upper contact pin 11 and the lower contact pin 12 and elastically supporting the upper contact pin 11 and the lower contact pin 12. The upper contact pin 11 and the lower contact pin 12 have the same shape.

The upper contact pin 11 includes a pair of fixing protrusions 11a protruding left and right, and the lower contact pin 12 also includes a pair of fixing protrusions 12a protruding left and right. Individual fixing protrusions 11a and 12a support the spring 30 and serve as a stopper that limits the upward and downward stroke range within the socket body. Reference numerals 11b and 12b indicate the upper and lower tip portions that are in direct contact with a lead of the IC and a terminal (pad) of the test PCB at the upper contact pin 11 and lower contact pin 12, respectively.

Referring back to FIGS. 2 to 4, the socket body 110 includes: an upper body portion 111 provided with a first support portion 111a that limits the upward movement of the probes 10 and 20; and a lower body portion 112 provided with a second support portion 112a that limits the downward movement of the probes 10 and 20 and is assembled with the upper body portion 111. The socket body 110 may be made of insulating materials such as FR4, Teflon, PI, FRS, or known PCB materials or FPCB materials, but is not limited thereto.

The first support portion 111a and the second support portion 112a may be provided by a step portion formed by a difference in diameter between the ground hole 110a and the signal hole 110b, respectively. The fixing protrusions 11a and 12a of individual probes 10 and 20 are supported by a step portion to limit the upward and downward stroke range of the probes 10 and 20.

Preferably, the ground hole 110a of the socket body 110 is formed with the conductive ground plating layer 121, and in addition to the conductive ground plating layer 121, an outer plating layer 122 may also be applied on the upper and lower surfaces of the socket body 110. The ground plating layer 121 may increase a grounding effect by directly contacting the ground probe 10 and may serve to shield noise between adjacent signal probes 20. Meanwhile, in the present embodiment, although the ground plating layer 121 of the ground holes 110a adjacent to each other is illustrated such that the outer plating layer 122 is isolated and formed locally, the outer plating layers of two or more neighboring ground holes may be connected to each other without direct contact with the signal probe, which will be explained again in detail in the related drawings.

In the present embodiment, the outer plating layer 122 is applied to all the upper and lower surfaces of the upper body portion 111 and the lower body portion 112, so that a plating layer is also formed between assembly surfaces of the upper body portion 111 and the lower body portion 112, but such plating layer between the assembly surfaces may be absent depending on the manufacturing process.

The shielding element 130 is provided by a conductive member penetrating the upper and lower surfaces of the socket body 110 to shield noise between the signal probes 120 that are the nearest neighbors.

Preferably, the shielding element 130 includes: a via hole 131 formed through the upper and lower surfaces of the socket body 110; and a conductive shield plating layer 132 formed on the surface of the via hole 131. Meanwhile, as another example, the shielding element may be provided as a conductive wire or rod extending through the upper and lower surfaces of the socket body.

To be specific, referring to the FIG. 2, the signal hole adjacent to the reference signal hole S0 includes a second signal hole S2 located on the x-axis and y-axis, a first ground hole G1 is located between the reference signal hole S0 and the second signal hole S2, and noise shielding between the signal probes of the reference signal hole S0 and the second signal hole S2 may be achieved by the ground plating layer 121 applied to the first ground hole G1. Meanwhile, the signal hole nearest to the reference signal hole S0 is a first signal hole S1 located diagonally, and the shielding element is located between the reference signal hole S0 and the first signal hole S1 so that noise shielding may be achieved between the signal probes of the reference signal hole S0 and the first signal hole S1. Thus, between the reference signal hole S0 and the adjacent signal holes S1 and S2, crosstalk between signal probes may be prevented by the ground plating layer of the ground hole 110a and the shielding element 130. Meanwhile, in the present embodiment, although only one shielding element 130 is exemplified to be disposed approximately in the center between adjacent signal holes, it should be understood that, considering the operating frequency of an IC to be inspected, lead (ground/signal) pattern, lead pitch, probe size, etc., there may be two or more shielding elements to increase the noise shielding effect between signal probes, and that the positions of the shielding elements may also be changed in various ways.

The ground plating layer 121 and the shield plating layer 132 may be, for example, a conductive material such as gold, copper, or nickel, but are not limited thereto.

The socket device may be manufactured as follows. As an example, the upper body portion 111 and the lower body portion 112 are manufactured by hole-processing an insulating member to form the first support portion 111a, the second support portion 112a, and the via hole 131. Then, the signal hole 110b is masked in the upper body portion 111 and the lower body portion 112, and the ground hole 110a and via hole 131 are plated. Next, the upper body portion 111 and the lower body portion 112 are assembled together with the probes 10 and 20 to manufacture the socket device. On the other hand, as another example, the plating treatment of the upper body portion 111 and the lower body portion 112 may be accomplished by first plating the entire body and then selectively etching the signal hole 110b.

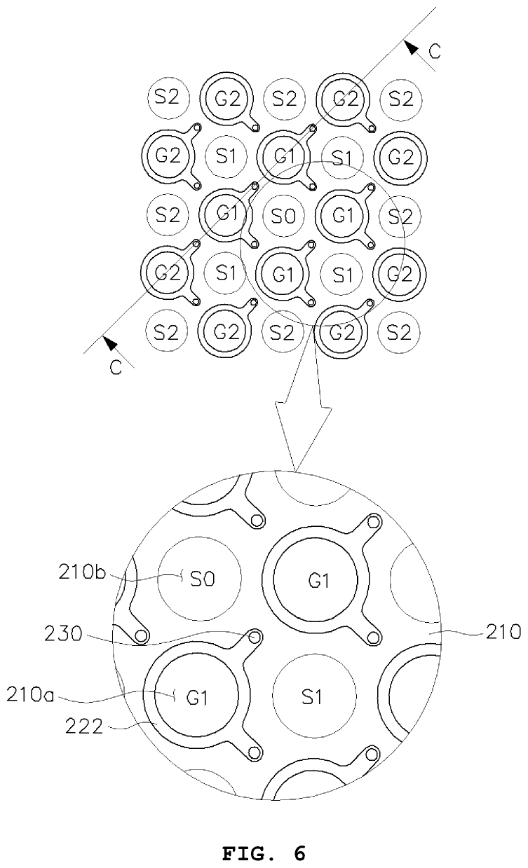

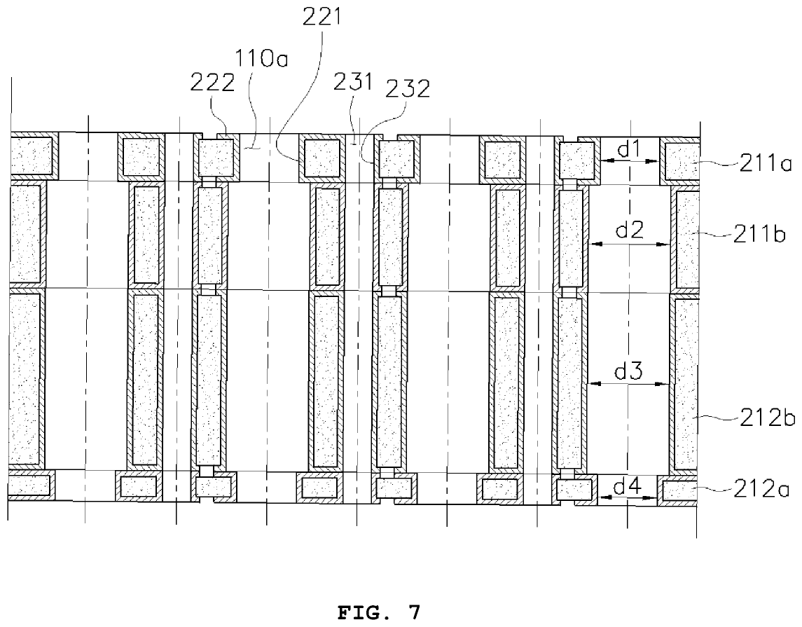

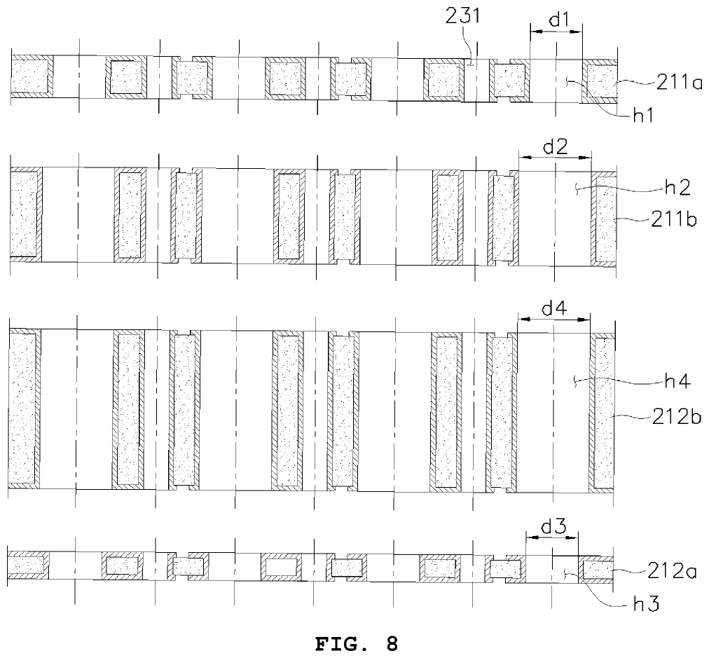

FIG. 6 is a plan view of a socket device according to another embodiment of present disclosure, FIG. 7 is a cross-sectional view taken along line C-C of FIG. 6, and FIG. 8 is an exploded view of FIG. 7.

Referring to FIGS. 6 to 8, as in the previous embodiment, a socket device according to the present embodiment includes: an insulating socket body 210 with a ground hole 210a and a signal hole 210b to accommodate a ground probe and a signal probe, respectively; a conductive ground plating layer 221 formed on the surface of the ground hole 210a; and a conductive shielding element 230 provided to penetrate the upper and lower surfaces of the socket body 210.

Preferably, in this embodiment, a shield plating layer 232 is electrically connected to the ground plating layer 221.

The socket body 210 has an outer plating layer 222 formed around openings at the top and bottom of the ground hole 210a, and the outer plating layer 222 may be connected to the ground plating layer 221 as one plating layer. The outer plating layer 222 may be formed on the outer surfaces of the upper and lower portions of the socket body 210 to the extent that the outer plating layer 222 does not come into direct contact with the signal probe. In particular, the outer plating layer 222 may be connected to the shield plating layer 232, which is the shielding element 230, to form one plating layer. In the present embodiment, one ground plating layer 121 is shown to be electrically connected to two adjacent shielding elements 230. In this way, the ground plating layer 121 is electrically connected to the shield plating layers 232 of the adjacent shielding elements 230, thereby increasing the grounding effect by increasing the grounding area.

Preferably, the upper body portion 211a and 211b and the lower body portion 212a and 212b each consist of two body portions. To be specific, the upper body portion 211a and 211b is composed of: a first upper body portion 211a through which a first guide hole h1 is formed where an upper tip 11b of the probe (see FIG. 5) protrudes; and a second upper body portion 211b through which a first receiving hole h2 having a larger inner diameter than the first guide hole h1 and communicating with the first guide hole h1 is formed, and assembled with the first upper body portion 211a. The lower body portion 212a and 212b is composed of: a first lower body portion 212a through which a second guide hole h3 is formed where a lower tip 12b of the probe (see FIG. 5) protrudes; and a second lower body portion 212b through which a second receiving hole h4 having a larger inner diameter than the second guide hole h3 and communicating with the second guide hole h3 and the first receiving hole h2 is formed, and assembled with the second upper body portion 211b and the first lower body portion 212a.

The inner diameter d2 of the first receiving hole h2 is larger than the inner diameter d1 of the first guide hole h1 (d1<d2), and the upper body portion 211a and 211b provides a support portion by the step formed on the assembly surface of the first upper body portion 211a and the second upper body portion 211b, thereby restricting the upward movement of the probe.

Next, the inner diameter d4 of the second receiving hole h4 is larger than the inner diameter d3 of the second guide hole h3 (d3<d5), and the lower body portion 212a and 212b provides a support portion by the step formed on the assembly surface of the first lower body portion 212a and the second lower body portion 212b, thereby restricting the downward movement of the probe.

As described in the previously embodiment, the socket device may be manufactured by hole-processing an insulating member to form the first upper body portion 211a, the second upper body portion 211b, first lower body portion 212a, and the second lower body portion 212b, and then the signal hole 210b is masked in the individual body portions 211a, 211b, 212a, and 212b, and the ground hole 210a and via hole 231 are plated. Next, the individual body portions 211a, 211b, 212a, and 212b are assembled together with the probes to manufacture the socket device. On the other hand, as another example, the plating treatment of the individual body portions 211a, 211b, 212a, and 212b may be accomplished by first plating the entire body and then selectively etching the signal hole 210b.

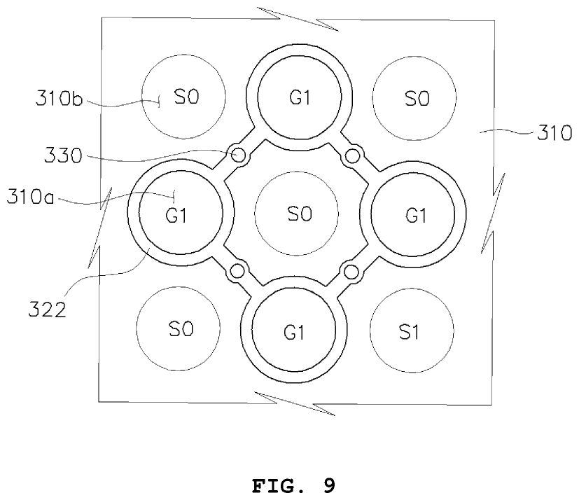

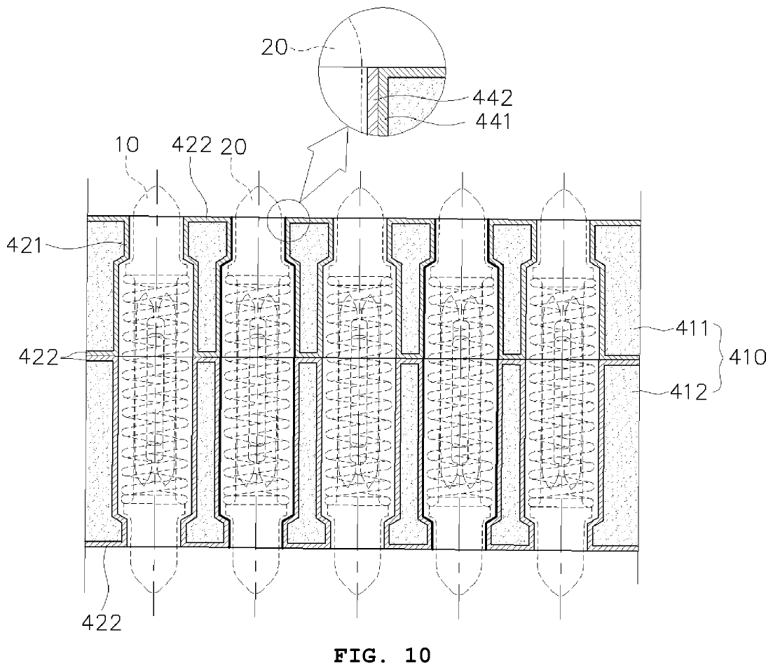

FIG. 9 is a plan view of a socket device according to still another embodiment of present disclosure.

As shown in FIG. 9, as in the previous embodiment, a socket device according to the present embodiment includes: an insulating socket body 310 with a ground hole 310a and a signal hole 310b to accommodate a ground probe and a signal probe, respectively; a conductive ground plating layer formed on the surface of the ground hole 310a; and a conductive shielding element 330 provided to penetrate the upper and lower surfaces of the socket body 310.

Preferably, in this embodiment, the socket body 310 has an outer plating layer 322, which is electrically connected to the ground plating layer, formed on the upper and lower surfaces of the socket body, and the outer plating layer 322 is connected, together with the shielding element 330, to the outer plating layer 322 of the adjacent ground hole 310a as one plating layer. In the present embodiment, four ground holes G1 are illustrated to be arranged adjacent to a reference signal hole S0, and the outer plating layers 322 of the four ground holes G1 are connected to each other as one plating layer together with the shielding elements 330.

In this way, in the present disclosure, the ground plating layer applied to any ground hole 310a may be electrically connected in various forms to the ground plating layer of the adjacent ground hole 310a along with the shielding element 330 by the outer plating layer 322. In addition, to the extent that the outer plating layer does not come into direct contact with the signal probe, the grounding area may be increased by increasing the area ratio of the plating layer to the total surface area of the insulating socket body, thereby improving the grounding effect and enhancing the noise shielding effect between adjacent signal probes.

FIG. 10 is a cross-sectional view of a socket device according to still another embodiment of present disclosure.

Referring to FIG. 10, as in the previous embodiment, a socket device according to the present embodiment includes: an insulating socket body 410 with a ground hole and a signal hole to accommodate a ground probe 10 and a signal probe 20, respectively; and a conductive shielding element provided to penetrate the upper and lower surfaces of the socket body 410.

Preferably, in this embodiment, a plating layer is formed on the entire socket body 410, including the signal hole, and only the signal hole is insulated to insulate the signal probe 20 and the plating layer.

In the present embodiment, the socket body 410 includes an upper body portion 411 and a lower body portion 412, so that the probes 10 and 20 are provided to be compressible in the vertical direction within the socket body 410. In the socket body 410, a ground plating layer 421 is applied to the ground hole whereas a signal plating layer 441 is applied to the signal hole, and an outer plating layer 422 is applied to all the upper, lower, and assembly surfaces of the socket body 410 to form a plating layer over the entire surface of the socket body 410. Meanwhile, the signal plating layer 441 is additionally coated with an insulating layer 442 to electrically insulate the signal probe 20. The insulating layer 442 may be selectively formed on top of the signal plating layer 441 by a vapor deposition process (CVD) after plating the socket body 410. The insulating layer 442 may be Si oxide or nitride, and Al oxide or Zr oxide may be used, but is not limited thereto.

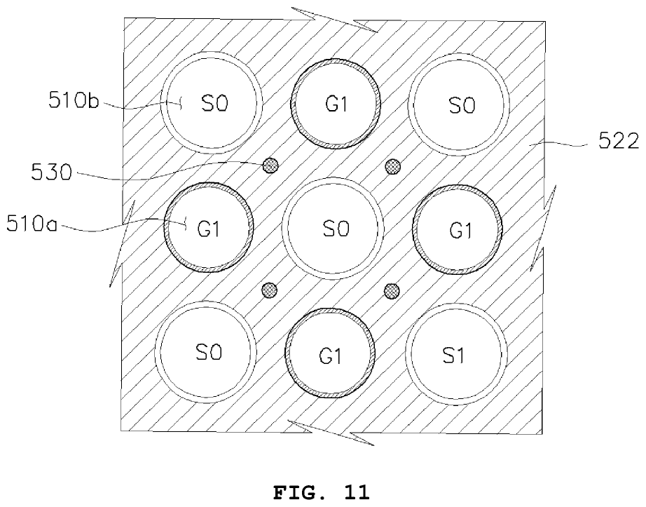

FIG. 11 is a plan view of a socket device according to still another embodiment of present disclosure.

As shown in FIG. 11, as in the previous embodiment, a socket device according to the present embodiment includes: an insulating socket body with a ground hole 510a and a signal hole 510b; a conductive ground plating layer formed on the surface of the ground hole 510a; and a conductive shielding element 530 provided to penetrate the upper and lower surfaces of the socket body.

Preferably, in this embodiment, the socket body is formed with an outer plating layer 522 that is electrically connected to the ground plating layer, and the outer plating layer 522 is formed on the entire upper surface of the socket body along with the shielding element 530 to the extent that the outer plating layer 522 does not directly contact the signal probe. In the present embodiment, the shielding element 530 is shown as a solid conductive wire or rod rather than a plating layer formed in the hole. Although not shown, an outer plating layer may be formed on the entire lower surface of the socket body to the extent that the outer plating layer does not directly contact the signal probe. As previously described, in this way, a conductive layer is formed on the entire outer surface of the socket body to maximize the grounding area, thereby improving the grounding effect and enhancing the noise shielding effect between adjacent signal probes.

As above, although the present disclosure has been described with limited embodiments and drawings, the scope of the present disclosure is not limited thereto, and various modifications and variations may be made by those skilled in the art in the technical field to which the present disclosure belongs within the scope of equivalency of the technical idea of the present disclosure and the claims set forth below.

What is claimed is:

1. A socket device for testing integrated circuits (ICs) including ground probes and signal probes, the socket device comprising:
an insulating socket body having ground holes to accommodate the ground probes and signal holes to accommodate the signal probes;
a conductive ground plating layer formed on a surface of each of the ground holes; and
a conductive shielding element provided to penetrate upper and lower surfaces of the socket body to shield noise between adjacent signal probes.

2. The socket device of claim 1, wherein the shielding element is placed between signal holes that are the nearest neighbors to each other.

3. The socket device of claim 2, wherein the shielding element comprises:
a via hole formed through the upper and lower surfaces of the socket body; and
a conductive shield plating layer formed on a surface of the via hole.

4. The socket device of claim 3, wherein the shield plating layer is electrically connected to the ground plating layer.

5. The socket device of claim 1, wherein the socket body comprises:
an upper body portion provided with a first support portion supporting a top of each of the probes; and
a lower body portion provided with a second support portion supporting a bottom of each of the probes and assembled with the upper body portion.

6. The socket device of claim 5, wherein the upper body portion comprises:
a first upper body portion through which a first guide hole is formed where an upper tip of each of the probes protrudes; and
a second upper body portion through which a first receiving hole having a larger inner diameter than the first guide hole and communicating with the first guide hole is formed, and assembled with the first upper body portion, and
the lower body portion comprises:
a first lower body portion through which a second guide hole is formed where a lower tip of each of the probes protrudes; and
a second lower body portion through which a second receiving hole having a larger inner diameter than the second guide hole and communicating with the second guide hole and the first receiving hole is formed, and assembled with the second upper body portion and the first lower body portion.

7. The socket device of claim 1, further comprising:
a conductive signal plating layer formed on a surface of each of the signal holes; and
an insulating layer formed on a surface of the signal plating layer to electrically insulate each of the signal probes and the signal plating layer.
